(19) United States
(12) Patent Application Publication
(10) Pub. No.: US 2017/0216970 A1
(43) Pub. Date: Aug. 3, 2017

(54) BERNOULLI PROCESS HEAD

(71) Applicant: M-SOLV LTD., Oxford (GB)

(72) Inventor: David Charles MILNE, Chipping Norton (GB)

(73) Assignee: M-SOLV LTD., Oxford (GB)

(21) Appl. No.: 15/515,104

(22) PCT Filed: Sep. 15, 2015
(86) PCT No.: PCT/GB2015/052667

§ 371 Date: Mar. 28, 2017

(30) Foreign Application Priority Data
Sep. 30, 2014 (GB) 1417261.3

(51) Int. Cl. B23K 26/14; B23K 26/04; H01L 21/683

(52) U.S. Cl. CPC B23K 26/1438; H01L 21/6838; B23K 26/048

(57) ABSTRACT

A process head for processing a substrate using a laser beam, comprising: an optical unit including at least one optical element for directing the laser beam; a plurality of Bernoulli air bearings arranged to surround an optical axis of the optical element and configured to eject a first fluid flow for producing an attractive force between said Bernoulli air bearing and said substrate by the Bernoulli principle, so as to maintain a substantially constant spacing between said optical element and said substrate.

The present invention relates to a process head for performing laser processing of a substrate.

In particular, the present invention relates to processing using a pulsed laser to ablate organic, inorganic, or metallic material layers from a substrate surface so as to pattern the material layers with high precision. Such applications include but are not limited to the manufacture of flat panel displays, touch panel displays and photovoltaic panels. These applications often require thin, flexible substrates less than 1.5 mm in thickness with material layers having thicknesses of less than 1 μm.

During the laser processing, the substrate and a process head are supported such that they are moveable relative to each other in two dimensions (the X-Y plane). The process head includes optics for focusing the laser beam to a specific point at or near to the substrate surface (in the Z-axis direction). Energy from the pulsed laser is transferred to the material to ablate portions of the substrate to form a desired pattern or structure.

In many cases, to pattern the substrate precisely, it is necessary that the relative position of the focal point of the focusing optics and the substrate, in the Z-axis, is fixed. If the relative position of the focal point of the focusing optics and the substrate is allowed to fluctuate too much, the energy density of the laser beam may be insufficient at the substrate surface to ablate the material layer or may be too high at other positions so as to damage the substrate, further material layers or material layers on the opposite side of the substrate. It is also important that the process head and the substrate do not come into contact with each other as this could damage the substrate or material layers. Therefore it is necessary to maintain a constant gap size in the Z-direction between the process head (for example specifically the focusing optics) and the substrate surface.

The fluctuations in the relative position of the focal point of the focusing optics and substrate surface may be caused by curvature of the substrate due to the way in which it is supported. In order to prevent contamination of the material layers on the substrate surfaces, the portion of the substrate which is to be processed is preferably largely unsupported; the substrate may, for example, be supported at a limited number of positions, for example at the edges. The flexibility of a thin substrate means that unsupported regions may flex or sag under their own weight, eg by up to 1 mm. This can occur whether the substrate is supported horizontally, vertically or obliquely. Variations in the relative position of the focal point of the focussing optics and substrate surface may also occur due to variations in the thickness of one or more of the material layers of the substrate.

There have been a number of attempts to overcome the above mentioned problems. Devices have been developed to automatically fix the relative position of the focal point of the focussing optics and substrate surface. These are generally referred to as auto-focussing devices.

GB 2400063 A discloses a process head which includes a focussing lens linked to an air powered puck, or air bearing, to automatically control the location of a focus position of a laser beam. The puck has an annular cross-section with an inner aperture. The interior of the puck (that is the puck body as opposed to the inner aperture) is fed with air which flows uniformly out of the underside of the puck body. The airflow asserts a repelling force on the substrate causing the puck to hover above the surface of the substrate on an air cushion.

However, the process head of GB 2400063 A is ill suited for processing the substrate close to the edges of the substrate. As the laser beam approaches the edge of the substrate, at least some of the air flow from the puck is no longer directed onto the substrate so the force separating the substrate and the puck is suddenly reduced. As the puck is biased in a direction toward the substrate (for example by gravity), this can result in the puck contacting and damaging the substrate. Further, if the puck completely crosses an edge of the substrate, the biasing force may result in the puck dropping below the level of the substrate. When the puck is moved back to a position over the substrate it will then impact the edge of the substrate. A puck of this type may also suffer from oscillation in the Z-axis direction as it ‘bounces’ on the cushion of air supporting it unless the exhaust of the puck is carefully designed. If the substrate is unsupported, the repelling force between the puck and the substrate may also tend to increase the degree of sag of the substrate.

GB 2439529 A discloses a process head which includes a focussing lens linked to an air puck to automatically control the location of a focus position of a laser beam. However, unlike the process head disclosed in GB 2400063 A, the optical axis of the focussing lens is offset from the puck. GB 2439529 A describes a puck where fluid enters the gap between the substrate surface and the puck towards the outside of the puck so creating a repelling force between the puck and the substrate (similar to GB 2400063 A) and addresses the problem with processing the substrate close to the edge by offsetting the puck from the focussing lens axis. By doing so, the laser beam can process the substrate near the edges while the puck remains completely on the substrate. However, this solution has a number of drawbacks. The process head can only process up to the edge of the substrate in the direction of the focussing lens axis from the puck. If the focussing lens is offset from the puck along a diagonal of the rectangular substrate, the process head can only process part of the substrate along two adjoining edges. In order to process all of the rectangular substrate, at least four process heads and four laser beams are required. GB 2439529 A also discloses that two offset focussing lenses can be supported by a single puck. However, at least two process heads and at least four laser beams would still be required to process a single rectangular substrate. Further, because the focussing lens axis is offset from the puck, the relative position of the focal point of the focussing lens and the substrate surface coinciding with the focussing lens axis is not directly controlled by the puck so variation in the position of the substrate surface coinciding with the focussing lens axis may not be adequately compensated for.

GB 2439529 A also mentions a puck where fluid enters the gap between the substrate surface and the puck at the centre of the puck so creating an attractive force between the puck and the substrate (a so called Bernoulli puck) and a puck where fluid enters the gap between the substrate surface and the puck around the outside of the puck and a vacuum is applied to the centre region so that the vacuum and fluid pressure counterbalance to stabilize the puck, but provides no further description thereof or of their use.

The present invention aims to at least partially address some of the problems identified above.

According to an aspect of the invention there is provided process head for processing a substrate using a laser beam, comprising: an optical unit including at least one optical element for directing the laser beam; a plurality of Bernoulli air bearings arranged to surround an optical axis of the optical element and configured to eject a first fluid flow for producing an attractive force between said Bernoulli air bearing and said substrate by the Bernoulli principle, so as to maintain a substantially constant spacing between said optical element and said substrate.

The plurality of Bernoulli pucks may each comprise: a flat surface; and a substantially central orifice through which the first fluid flow is ejected. Said flat surface of each Bernoulli puck may be circular. Said flat surface of each Bernoulli unit may be polygonal or square. Said orifice may be arranged to eject said fluid flow from said Bernoulli puck in a direction perpendicular to said flat surface and from the centre of said flat surface. The process head may comprise three, four or more Bernoulli pucks.

The process head may further comprise: a process area in which said processing can occur, surrounding the optical axis and bounded by said substrate when said substrate is being processed by the laser beam; and an environment controlling unit configured to provide a second fluid flow through the process area for controlling the environment in the process area. The environment controlling unit may configured to remove from the process area debris resulting from the processing.

According to a second aspect of the invention there is provided an apparatus for processing a substrate using a laser beam, the apparatus comprising a support member for supporting the substrate at a first position of the substrate; and the process head of the first aspect of the invention; wherein the process head is configured to support the substrate at a second position, different from the first position.

According to a third aspect of the invention there is provided a method of supporting a substrate for laser processing, the method comprising: supporting a first portion of the substrate by attraction using the Bernoulli process head of the first aspect of the invention.

Such Bernoulli air bearings are commonly referred to as Bernoulli pucks and these terms are used interchangeably herein.

Other aims and preferred and optional features of the invention will be apparent from the following description and the subsidiary claims of the specification.

The invention will now be further described, merely by way of example, with reference to the accompanying drawings in which:

FIG. 1 shows a schematic of a process head which may be used in one aspect of the invention;

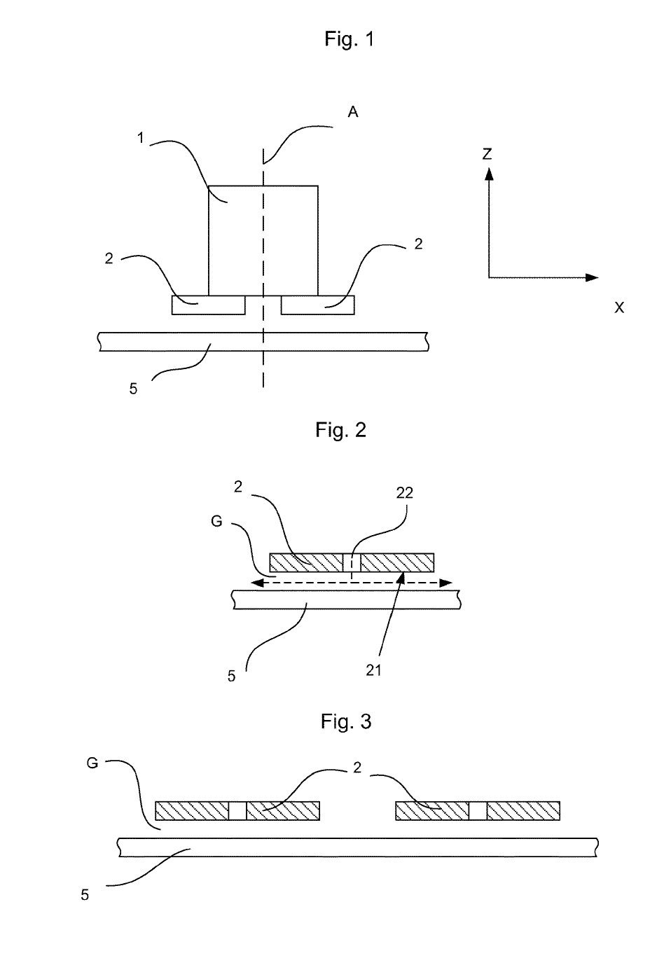

FIG. 2 shows a schematic cross-sectional view of a Bernoulli puck and a substrate to illustrate their function;

FIG. 3 shows a plurality of Bernoulli pucks and how they regulate the distance from a substrate;

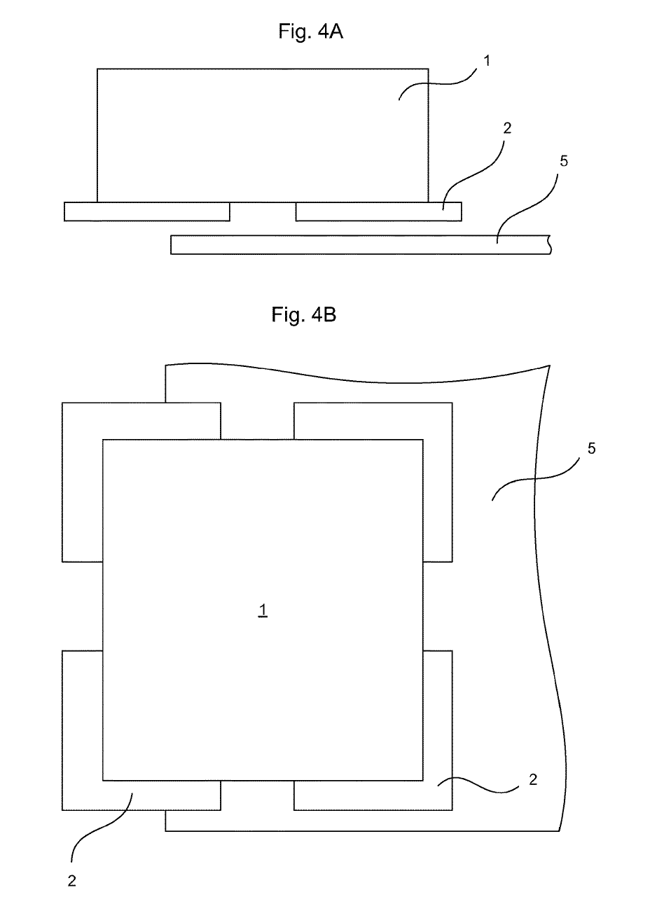

FIGS. 4A and 4B respectively show a side view and a plan view of the process head operating close to the edge of the substrate;

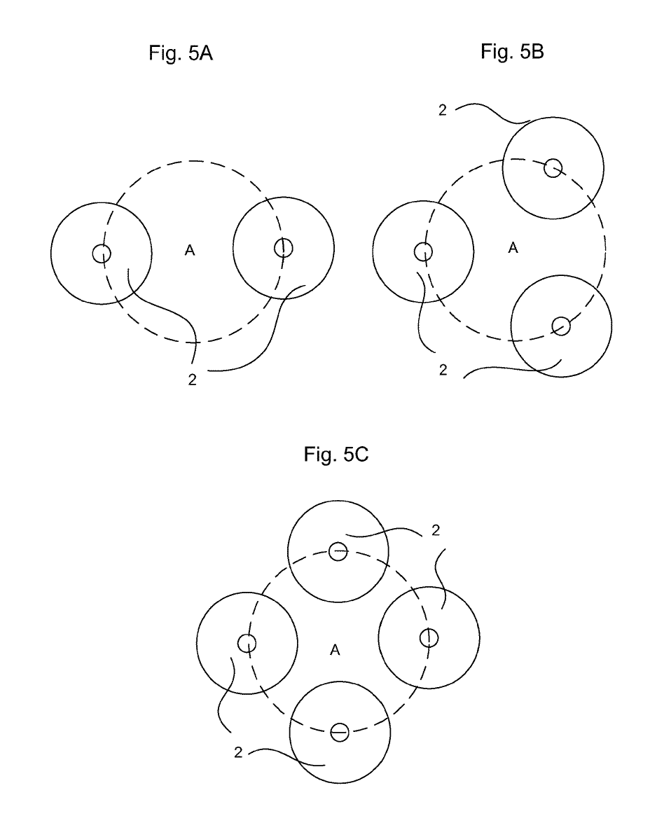

FIGS. 5A to 5C show a number of suitable ways of arranging Bernoulli pucks in relation to a process head in aspects of the invention;

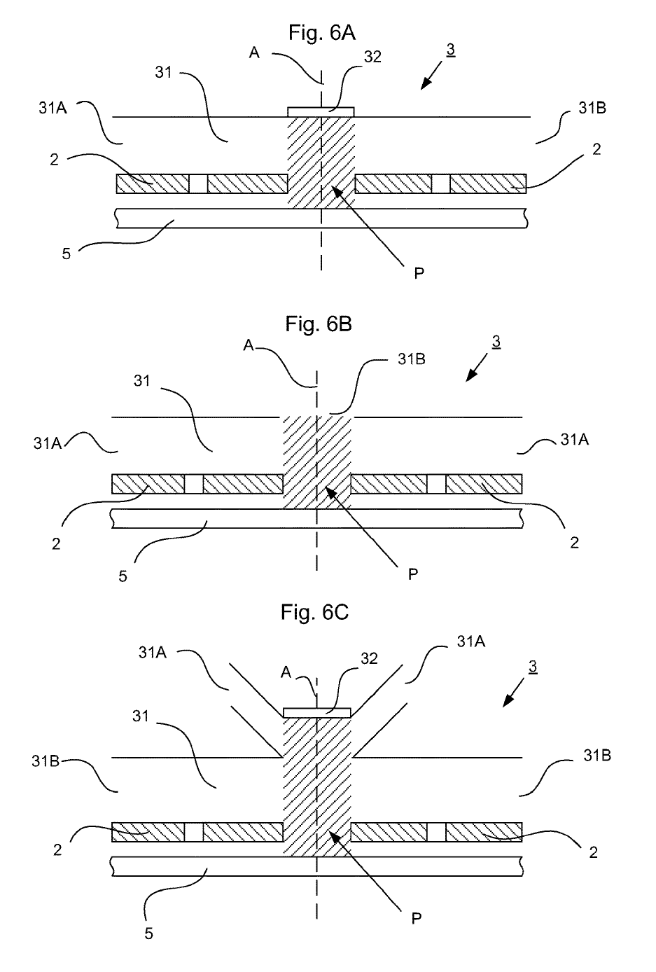

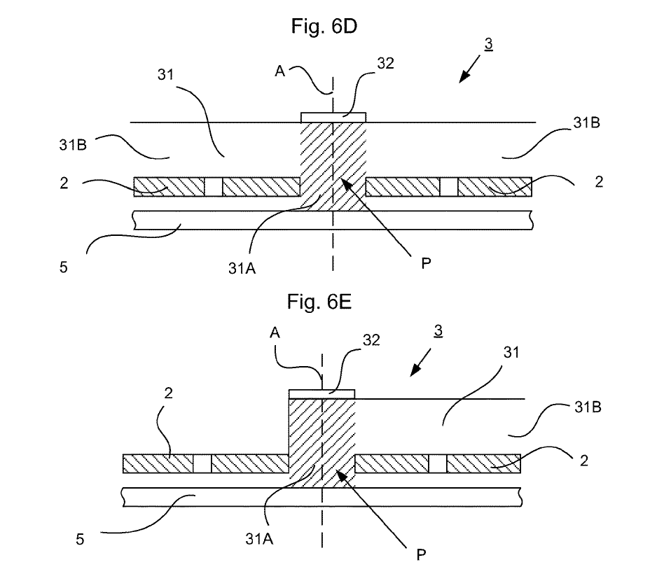

FIGS. 6A to 6E show a number of configurations of an debris extraction unit in such arrangements;

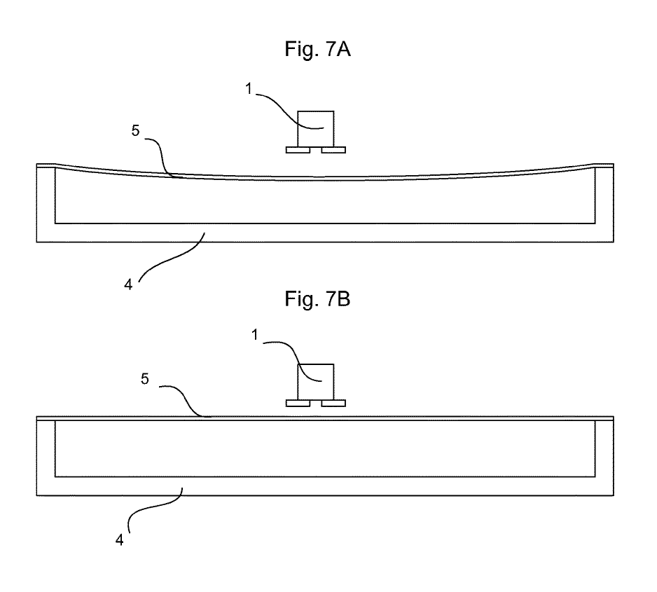

FIGS. 7A and 7B shows an embodiment of the invention comprising a process head and a support member for supporting the substrate, illustrating how the process head is used to support a portion of the substrate.

FIG. 1 shows a schematic diagram of a process head according to an aspect of the invention. The process head includes an optical unit 1 for directing a laser beam toward a substrate 5 and/or focusing a laser beam at a focal point. The optical unit 1 may include one or more optical elements, for example lenses and/or mirrors, for directing the laser beam and/or focusing the laser beam at a desired focal spot. The overall focal length of the optical unit may be fixed or, more preferably, may be variable. The laser beam, enters the optical unit 1 and is directed and/or focussed by the optical element(s) of the optical unit towards the substrate 5, i.e. in the Z-direction. The laser beam preferably propagates along an optical axis A of the optical element(s). The process head shown in FIG. 1 also includes a plurality of Bernoulli air bearings 2, or pucks, arranged to surround the optical axis A of the optical element(s). The Bernoulli pucks 2 are arranged to maintain a substantially constant spacing between the optical unit 1 and the surface of a substrate 5. The position of the Bernoulli pucks 2 is preferably fixed relative to the optical unit 1.

FIG. 2 a cross-sectional view of a Bernoulli puck 2 and a substrate 5 to illustrate their function. The Bernoulli pucks 2 preferably each comprise a flat surface 21 and a substantially central orifice 22, from which a first fluid flow is ejected. The flat surface 21 and the substrate 5 confine the fluid ejected from the orifice 22 to follow a path parallel to the flat surface 21 and the substrate 5. As shown in FIG. 2, when the Bernoulli puck is relatively close to the substrate, the Bernoulli puck 2 and the substrate 5 are attracted towards each other but maintained at a substantially constant spacing from each other by the Bernoulli effect, as illustrated by gap G between the Bernoulli puck 2 and the substrate 5. The size of the gap G is self regulating, i.e. if the gap size increases or if the gap size is reduced, the Bernoulli effect counteracts this. The gap size is determined by the fluid flow rate, the size of the orifice 22 and geometry of the arrangement such as the size and shape of the flat surface 21 of the Bernoulli puck 2. The gap may, for example, be around 100 microns and maintained within plus or minus 10 microns. A pressure regulator may be provided to enable the size of the gap to be controlled. The flow rate should be sufficient to ensure the Bernoulli Effect causes the Bernoulli puck 2 and the substrate 5 to be attracted towards each other in the manner described above

There exists a threshold distance between the Bernoulli puck 2 and the substrate 5, below which the Bernoulli effect is effective in attracting the puck and substrate towards each other but maintaining a constant spacing therebetween. The threshold distance also depends on the flow rate of the fluid ejected from the Bernoulli pucks 2, the size and shape of the Bernoulli puck 2 and the size and shape of the orifice 21.

In a typical arrangement, this threshold distance may be a few millimeters and the gap G between 50 and 200 microns.

The flat surface 21 of each Bernoulli puck may be circular or may be polygonal e.g. a square or another regular polygon. The orientation of a polygonal puck is not particularly limited, however it is preferable in the case of a regular polygon that the surface 21 is oriented such that it is mirror symmetric about an axis passing through the centre of the puck 2 and the optical axis A of the optical element(s) to ensure a more uniform air flow. The orifice 21 is preferably arranged to eject the fluid flow from the Bernoulli puck 2 in a direction perpendicular to the flat surface 21 and from the centre of said flat surface 21 so that the fluid flow is substantially uniform across the Bernoulli puck 2. The orifice 22 may be in the form of a single cylindrical hole through the centre of the flat surface 21. Typically, the diameter of the Bernoulli puck 2 is between 15 mm and 40 mm. Typically, the diameter of the orifice 22 is between 1 mm and 5 mm.

By providing the Bernoulli pucks 2 so as to surround the optical axis A of the optical element(s), the process head can accurately control the relative positions of the optical unit 1 and the substrate 5 on both sides of the optical unit 1. Therefore the distance between the optical unit 1 and the part of substrate 5 in line with the optical axis A, is regulated more effectively. Also, if the substrate is supported at its edges and so has a tendency to sag, the provision of Bernoulli pucks on more than one side of the process area (where processing occurs) is effective in supporting the substrate in a substantially flat manner as shown in FIG. 3.

Further, by providing the Bernoulli pucks 2 so as to surround the optical axis A of the optical element(s), the process head can operate effectively close to the edge of the substrate 5. Pucks which produce a repelling force between the puck and the substrate, such as in the prior art mentioned above, have to be biased towards the substrate, which may result in the puck impacting the substrate as it approaches an edge, due to a reduction in the repelling force produced by the puck. In an arrangement using Bernoulli pucks 2, such as in the present invention, on the other hand, the process head is typically biased away from the substrate 5, for example gravity acting on the substrate, to counteract the attractive force between the pucks and the substrate. In this case, if the Bernoulli force is reduced as one of the pucks passes over the edge of the substrate, the force biasing the process head away from the substrate automatically increases the gap between the process head and the substrate so reducing the risk of any impact.

Further, as shown in FIGS. 4A and 4B, arranging multiple Bernoulli pucks 2 to surround the optical axis A of the optical element(s) allows at least one Bernoulli puck 2 (and preferably more than one) to remain above the substrate 5 close to the edge. Thus, even though one puck may have passed over the edge of the substrate, the distance between the process head and the substrate is still regulated by the Bernoulli puck(s) remaining over the substrate.

FIGS. 5A-5C show a number of suitable ways of arranging the Bernoulli pucks 2 to surround the optical axis A of the optical element(s). These figures show the arrangement of the Bernoulli pucks with reference to X and Y axes. The X and Y axes shown preferably correspond to orthogonal directions in which the substrate 5 or process head is discretely moveable. The plurality of Bernoulli pucks are considered to surround the optical axis A of the optical element(s) if the smallest circle circumscribed by the centres of any two of the Bernoulli pucks 2 surrounds the optical axis A of the optical element(s).

FIG. 5A shows an embodiment in which the process head is supported by two Bernoulli pucks 2. In the specific embodiment shown, the Bernoulli pucks 2 are positioned axisymmetrically with respect to the optical axis A of the optical element(s). However, other arrangements of the two Bernoulli pucks 2 are possible, provided the Bernoulli pucks 2 are arranged to surround the optical axis A of the optical element(s), as defined above. Generally the two Bernoulli pucks 2 are preferably arranged on opposite sides of the optical axis A of the optical elements with respect to the X or Y axes or in opposite quadrants with respect to the X and Y axes.

FIG. 5B shows an embodiment in which the process head is supported by three Bernoulli pucks 2. In the specific embodiment shown, the Bernoulli pucks 2 are positioned axisymmetrically with respect to the optical axis A of the optical element(s). However, other arrangements of the two Bernoulli pucks are possible, provided the Bernoulli pucks 2 are arranged to surround the optical axis A of the optical element(s), as defined above. Generally, the three Bernoulli pucks 2 are preferably arranged so that there is at least one Bernoulli puck 2 on opposite sides of the optical axis A of the optical element(s) with respect to the X or Y axes. If more than two Bernoulli pucks 2 are provided it is preferable that a circle circumscribed by any three of the Bernoulli pucks 2 surrounds the optical axis of the optical element(s).

FIG. 5C shows an embodiment in which the process head is supported by four Bernoulli pucks 2. In the specific embodiment shown, the Bernoulli pucks 2 are positioned axisymmetrically with respect to the optical axis A of the optical element(s). However, other arrangements of the four Bernoulli pucks 2 are possible, provided the Bernoulli pucks 2 are arranged to surround the optical axis A of the optical element(s), as defined above. Generally, the four Bernoulli pucks 2 are preferably arranged so that there is at least one Bernoulli puck 2 on opposite sides of the optical axis A of the optical element(s) with respect to the X or Y axes or in opposite quadrants with respect to the X and Y axes. However, preferably, a Bernoulli puck 2 is provided in each quadrant.

The flat surfaces 21 of the plurality of Bernoulli pucks 2 should be coplanar and the Bernoulli pucks 2 are preferably identical. In a preferred arrangement, the Bernoulli pucks 2 may be formed on a single flat base plate to ensure they are coplanar to a high tolerance.

Although not shown in the figures, more than four Bernoulli pucks 2 can be provided. Generally, these Bernoulli pucks 2 are preferably arranged so that there is at least one Bernoulli puck 2 on opposite sides of the optical axis A of the optical element(s) with respect to the X or Y axes or in opposite quadrants with respect to the X and Y axes. However preferably a Bernoulli puck 2 is provided in each quadrant. More preferably, the Bernoulli pucks 2 are arranged axisymmetrically. Most preferably, the Bernoulli pucks 2 are specifically arranged axisymmetrically with respect to the optical axis A of the optical elements(s).

FIGS. 6A to 6E show embodiments of the invention which includes an environment control unit 3. A process area P in which said processing can occur can be defined such that the process area P surrounds the optical axis A of the optical unit and is bounded by the substrate 5, when the substrate 5 is being processed by the laser beam. The environment control unit 3 may be configured to provide a second fluid flow through the process area P to control the environment in the process area P for example by removing from the process area P debris resulting from processing the substrate 5 with the laser beam. As the laser beam ablates the substrate 5, debris may leave the substrate 5 and enter the process area 5. This debris can interfere with the processing or damage the process head or substrate 5 unless removed immediately.

In other arrangements, the second fluid flow may or provide a chemically active gas to assist processing, for example the environment control unit 3 may provide an oxygen rich gas which assists in the ablation process. In another arrangement, the environment control unit 3 may form a vacuum or partial vacuum in the process area P.

Integrating the environment control unit 3 with the Bernoulli process head described above means the environment control process benefits from the small clearance between the substrate and process head that the Bernoulli pucks 2 maintains. A small clearance means the environment control device 3 can more effectively control the environment, in particular the removal of debris from the process area.

The environment control unit 3 may typically comprise a duct or ducts 31 through which a fluid can flow into the process area at one location (an entrance duct 31A) and out of the process area at another location (an exit duct 31B). The fluid in the duct(s) 31 is subjected to a pressure gradient by providing one or both of a positive pressure source and a negative pressure source (relative to an ambient pressure). The fluid ejected from the Bernoulli pucks 2 may provide all or part of the positive pressure source, eg as described below in relation to FIG. 6D. FIGS. 6A to 6E show embodiments with different pressure gradients and different arrangements of ducts 31. Further ducts may include a window 32 to allow the laser beam to pass through.

FIG. 6A shows an arrangement with one entrance duct 31A and one exit duct 31B. A positive pressure source (not shown) may be provided on the side of the entrance duct 31A and/or a negative pressure source (not shown) may be provided on the side of the exit duct 31B. In this embodiment, the pressure gradient is provided such that the fluid enters the process area P substantially in a direction in the X-Y plane and exits the process area P substantially in a direction in the X-Y plane. In this embodiment, the entrance duct 31A and the exit duct 31B are on opposite sides of the process area P relative to the optical axis A. A window 32 defines the top of the process area.

FIG. 6B shows an arrangement with two entrance ducts 31A and one exit duct 31B. A positive pressure source (not shown) may be provided on the side of the entrance ducts 31A and/or a negative pressure source (not shown) may be provided on the side of the exit duct 31B. In this embodiment the pressure gradient is provided such that the fluid enters the process area P substantially in a direction in the X-Y plane and exits the process area P substantially in a direction in the positive Z-axis (upwards). In this embodiment, the two entrance ducts 31A are on opposite sides of the process area P while the exit duct 31B is located above the level of the entrance ducts 31A.

FIG. 6C shows an arrangement with two entrance ducts 31A and two exit ducts 31B. A positive pressure source (not shown) may be provided on the side of the entrance ducts 31A and/or a negative pressure source (not shown) may be provided on the side of the exit ducts 31B. In this embodiment the pressure gradient is provided such that the fluid enters the process area P substantially in the negative Z− direction (downwards) and exits the process area P substantially in a direction in the X-Y plane. In this embodiment, the two entrance ducts 31A are on opposite sides of the process area P close to the axis A and the exit ducts 31B are provided on opposite sides of the process area P but further from the axis A. Further, the entrance ducts 31A are located above the level of the exit ducts 31B. A window 32 defines the top of the process area.

FIG. 6D shows an arrangement with one entrance duct 31A and two exit ducts 31B. The fluid ejected from the Bernoulli pucks 2 provides a positive pressure source on the side of the entrance duct 31A and a negative pressure source (not shown) may be provided on the side of the exit ducts 31B. In this embodiment the pressure gradient is provided such that the fluid enters the process area P substantially in the positive Z-direction (upwards) and exits the process area P substantially in a direction in the X-Y plane. In this embodiment, the entrance duct 31A is located below the level of the exit ducts 31B and the exit ducts 31B are provided on opposite sides of the process area P. A window 32 defines the top of the process area.

FIG. 6E shows an arrangement with one entrance duct 31A and one exit duct 31B. The fluid ejected from the Bernoulli pucks 2 provides a positive pressure source on the side of the entrance duct 31A and a negative pressure source (not shown) may be provided on the side of the exit duct 31B. In this embodiment, the pressure gradient is provided such that the fluid enters the process area P substantially in the positive Z-direction (upwards) and exits the process area P substantially in a direction in the X-Y plane. In this embodiment, the entrance duct 31A is located below the level of the exit duct 31B. A window 32 defines the top of the process area.

As mentioned above, the process head and the substrate 5 may be biased away from each other. The attractive force generated by the Bernoulli pucks 2 counteracts this biasing force to maintain the Bernoulli puck 2 (and hence the process head) and the substrate 5 to within a predetermined distance of each other. The biasing force can be provided in one of three ways.

Firstly, the substrate 5 may remain fixed in the Z-axis while a biasing force is applied to the process head. This can be done using counterweights, magnets, etc. Secondly, the process head may remain fixed in the Z-axis, while a biasing force is applied to the substrate 5. The biasing force may be provided by gravity which causes the substrate 5 to sag away from the process head, for example if the substrate 5 is supported at the edges. Thirdly, the biasing force can be provided by a combination of both the first and second way. How the biasing force is provided is determined by the application. For a relatively rigid or thick substrate 5 it might be most suitable to provide the biasing force in the first way. For a relatively thin or flexible substrate 5 it might be most suitable to provide the biasing force in the second way.

FIG. 7 illustrates an embodiment of the invention comprising a process head and a support member, or chuck 4, for holding the substrate 5. The process head and the chuck 4 are moveable relative to each other in the X-Y plane, either by moving the process head, the chuck 4, or both. The chuck 4 may be a vacuum chuck, for example, which holds the substrate 5 in position by suction provided by a vacuum source. The chuck 4 may support the substrate 5 at a perimeter thereof while a central portion of the substrate 5, within the perimeter, is unsupported by the chuck 4. In this case, the substrate 5 sags in the region unsupported by the chuck 4, under gravity so as to bias the substrate 5 away from the process head (as shown in FIG. 7A). The process head is positioned a distance above the substrate 5 and attracts the substrate 5, so as to support it in the region unsupported by the chuck 4. As mentioned above, the substrate may thus be supported in a relatively flat manner (as shown in FIG. 7B).

The above described embodiments provide one or more of the following advantages over the prior art. Embodiments of the invention provide a simple arrangement, requiring a single process head for example, for processing at the edge of a substrate. Embodiments of the invention provides self-regulating spacing between the optical unit and the substrate. Multiple pucks surrounding the optical axis means the spacing is specifically regulated in the process area. Embodiments of the invention provide an integrated contactless support system (Bernoulli pucks), process head and optionally an environment control device. Embodiments of the invention bring the environment control device into very close proximity to the substrate surface.

1. A process head for processing a substrate using a laser beam, comprising:
an optical unit including at least one optical element for directing the laser beam;
a plurality of Bernoulli air bearings arranged to surround an optical axis of the optical element, each Bernoulli air bearing configured to eject a first fluid flow for producing an attractive force between said Bernoulli air bearing and said substrate by the Bernoulli principle, so as to maintain a substantially constant spacing between said optical element and said substrate.

2. The process head of claim 1, wherein:
the plurality of Bernoulli air bearings each comprise:
a flat surface; and
a substantially central orifice through which the first fluid flow is ejected.

3. The process head of claim 2, wherein:
said flat surface of each Bernoulli air bearing is circular.

4. The process head of claim 2, wherein:
said flat surface of each Bernoulli air bearing is polygonal or square.

5. The process head of claim 2, wherein:
said orifice is arranged to eject said fluid flow from said Bernoulli air bearing in a direction perpendicular to said flat surface and from the centre of said flat surface.

6. The process head of claim 1, comprising:
three, four or more Bernoulli air bearings.

7. The process head of claim 1, further comprising:
a process area in which said processing can occur, surrounding the optical axis and bounded by said substrate when said substrate is being processed by the laser beam; and
an environment controlling unit configured to provide a second fluid flow through the process area for controlling the environment in the process area.

8. The process head of claim 7, wherein:
the environment controlling unit is configured to remove from the process area debris resulting from the processing.

9. An apparatus for processing a substrate using a laser beam, the apparatus comprising:
a support member for supporting the substrate at a first position of the substrate; and
the process head as claimed in claim 1;
wherein the process head is configured to support the substrate at a second position, different from the first position.

10. A method of supporting a substrate for laser processing, the method comprising:
supporting a first portion of the substrate by attraction using the Bernoulli process head of claim 1.
